(19) United States
(12) Patent Application Publication
(10) Pub. No.: US 2010/0271149 A1
(43) Pub. Date: Oct. 28, 2010

(54) HIGH-FREQUECY MODULE FOR WIRELESS COMMUNICATIONS

(75) Inventors: PO-CHUAN HSIEH, Tu-Cheng (TW); SHOU-KUO HSU, Tu-Cheng (TW); YU-CHANG PAI, Tu-Cheng (TW); CHIEN-HUNG LIU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/471,339

(22) Filed: May 22, 2009

(30) Foreign Application Priority Data
Apr. 23, 2009 (CN) 200910301784.0

(51) Int. Cl. H03H 7/38

(52) U.S. Cl. 333/33

(57) ABSTRACT

A high-frequency module includes an antenna, an impedance matching circuit, and a transmission wire. The transmission wire is connected between the antenna and the impedance matching circuit. The transmission wire includes a dielectric layer, a signal layer, and two ground layers. The signal layer and the ground layers are located on the dielectric layer. The ground layers are located at opposite sides of the signal layer respectively. A space is formed between a signal and each ground layer.

### BACKGROUND

1. Technical Field

The present disclosure relates to high-frequency modules, and particularly, to a high-frequency module for wireless communications.

2. Description of Related Art

Generally, in a wireless communications system, a high-frequency module includes an impedance matching circuit for matching the impedance of a function module and an antenna. The impedance matching circuit usually includes a capacitor. A terminal of the capacitor is grounded by passing through a via hole, thus increasing the number of via holes needed. As a result, more vias holes tend to cause impedance mismatching in the wireless communications system.

### BRIEF DESCRIPTION OF THE DRAWINGS

FIG. 1 is a schematic block diagram of an exemplary embodiment of a high-frequency module connected to a function module, the high-frequency module includes an impedance matching circuit, and a transmission wire.

FIG. 2 is a circuit diagram of the impedance matching circuit of FIG. 1, in accordance with an exemplary embodiment.

FIG. 3 is a sectional view of the transmission wire of FIG. 1, in accordance with an exemplary embodiment.

### DETAILED DESCRIPTION

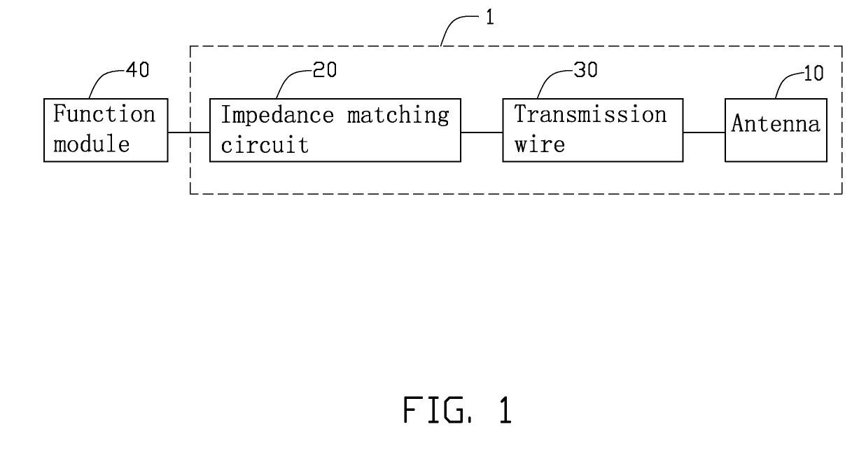

Referring to FIG. 1, an exemplary embodiment of a high-frequency module 1 for wireless communications is mounted on a printed circuit board. The high-frequency module 1 includes an antenna 10, an impedance matching circuit 20, and a transmission wire 30.

The antenna 10, the impedance matching circuit 20, and the transmission wire 30 are mounted on a same layer of the printed circuit board. The transmission wire 30 is connected between the antenna 10 and the impedance matching circuit 20. The impedance matching circuit 20 receives signals from a function module 40, and transfers the signals to the antenna 10 via the transmission wire 30. It can be understood that the function module 40 is a module that can generate signals in a wireless communications system, such as a Radio Frequency Identification module. The impedance matching circuit 20 matches impedance of the function module 40 and impedance of the antenna 10, to output the maximum power.

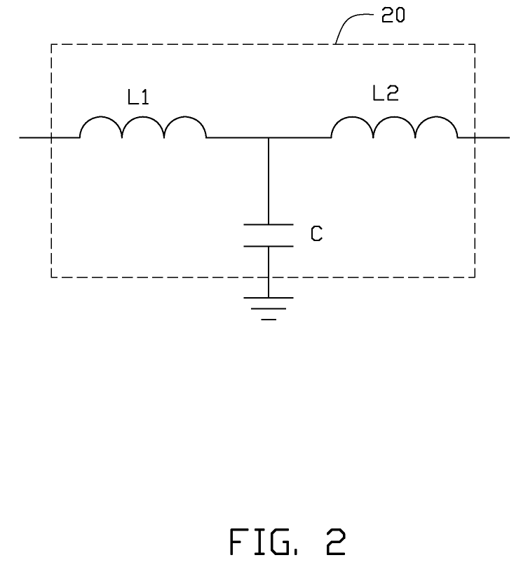

Referring to FIG. 2, the impedance matching circuit 20 includes a first inductor L1, a second inductor L2, and a capacitor C. A first terminal of the first inductor L1 is connected to the function module 40. A second terminal of the first inductor L1 is connected to the transmission wire 30 via the second inductor L2. A first terminal of the capacitor C is connected to the second terminal of the inductor L1. A second terminal of the capacitor C is grounded. It can be understood that the impedance circuit 20 can have other configurations, so long as circuit 20 still matches the impedance of the function module 40 to the impedance of the antenna 10.

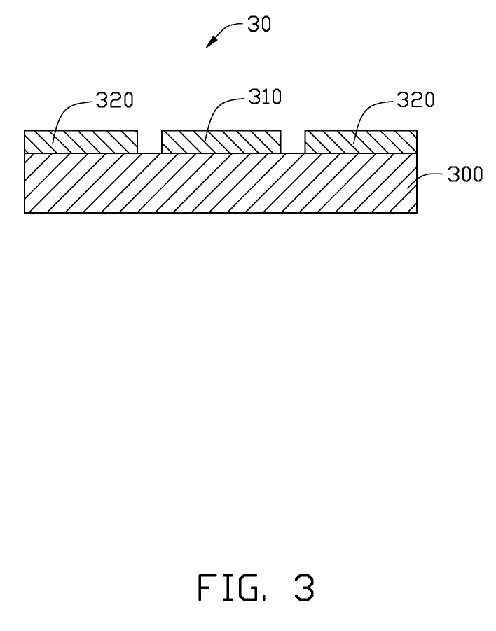

Referring to FIG. 3, the transmission wire 30 includes a dielectric layer 300, a signal layer 310, and two ground layers 320. The signal layer 310 and the ground layers 320 are located on the dielectric layer 300. The ground layers 320 are located at opposite sides of the signal layer 310 respectively. A space is formed between each ground layer 320 and the signal layer 310.

The impedance matching circuit 20 and the antenna 10 are mounted on the same layer of the printed circuit board, and the signal layer 310 and ground layers 320 are located on a same plane. As a result, the second terminal of the capacitor C is connected to the ground layer 320 to be grounded, and is not connected to a ground layer of the printed circuit board through via holes of the printed circuit board. In this way the number of via holes in the printed circuit board are reduced, thus avoiding impedance mismatching because of the via holes.

It can be understood that wires connected between the first inductor L1, the second inductor L2, and the capacitor C have the same structure as the transmission wire 30. In addition, the wire connected between the function module 40 and the impedance matching circuit 20 has the same structure as the transmission wire 30. As a result, the high-frequency module can avoid impedance mismatching.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A high-frequency module comprising:
an antenna;
an impedance matching circuit;
a transmission wire connected between the antenna and the impedance matching circuit, the transmission wire comprising:
a dielectric layer;
a signal layer located upon the dielectric layer;
two grounded ground layers located upon the dielectric layer, and at opposite sides of the signal layer correspondingly, wherein a space is formed between a signal and each ground layer.

2. The high-frequency module of claim 1, wherein the impedance matching circuit comprises a first inductor, a second inductor, and a capacitor, a first terminal of the first inductor is to be connected to a function module, a second terminal of the first inductor is connected to the transmission wire via the second inductor, a first terminal of the capacitor is connected to the second terminal of the inductor, and a second terminal of the capacitor is connected to one of the ground layers of the transmission wire.

3. The high-frequency module of claim 1, wherein wires in the impedance matching circuit are the same structure as the transmission wire.

4. The high-frequency module of claim 1, wherein wires between the function module and the impedance matching circuit are the same structure as the transmission wire.
